(19) United States
(12) Patent Application Publication
(10) Pub. No.: US 2025/0098217 A1
(43) Pub. Date: Mar. 20, 2025

(54) GATE-ALL-AROUND FIELD EFFECT TRANSISTOR STRUCTURES

(71) Applicant: QUALCOMM Incorporated, San Diego, CA (US)

(72) Inventors: Yan SUN, San Diego, CA (US); Shreesh NARASIMHA, Charlotte, NC (US); Deepak SHARMA, San Diego, CA (US)

(21) Appl. No.: 18/469,496

(22) Filed: Sep. 18, 2023

(51) Int. Cl. H01L 29/417; H01L 23/528; H01L 29/06; H01L 29/40; H01L 29/423; H01L 29/66; H01L 29/775

(52) U.S. Cl. CPC H10D 30/6729; H01L 23/5286; H10D 30/014; H10D 30/43; H10D 30/6735; H10D 62/121; H10D 64/01

(57) ABSTRACT

A field effect transistor (FET) structure and method for making the same is disclosed. In an aspect, a FET structure comprises a gate structure, disposed between a first vertical source/drain (S/D) structure and a second vertical S/D structure, the gate structure comprising a channel structure comprising a plurality of vertically-stacked, horizontal channels connecting the first vertical S/D structure to the second vertical S/D structure horizontally through a vertical metal gate structure that at least partially surrounds the plurality of horizontal channels. The FET also comprises a backside inter-layer dielectric (ILD) layer disposed below the vertical metal gate structure, wherein a first thickness of the vertical metal gate structure below a bottom channel of the plurality of horizontal channels is larger than a second thickness of the vertical metal gate structure between adjacent channels of the plurality of horizontal channels.

### BACKGROUND OF THE DISCLOSURE

### 1. Field of the Disclosure

This disclosure relates generally to semiconductor wafer process, and more specifically to gate-all-around (GAA) field effect transistors (FETs) structures and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a field effect transistor (FET) structure includes a gate structure, disposed between a first vertical source/drain (S/D) structure and a second vertical S/D structure, the gate structure comprising a channel structure comprising a plurality of vertically-stacked, horizontal channels connecting the first vertical S/D structure to the second vertical S/D structure horizontally through a vertical metal gate structure that at least partially surrounds the plurality of horizontal channels; and a backside inter-layer dielectric (ILD) layer disposed below the vertical metal gate structure and separated from some portions of the vertical metal gate structure by a shallow trench isolation (STI) layer, wherein a first thickness of the vertical metal gate structure below a bottom channel of the plurality of horizontal channels is larger than a second thickness of the vertical metal gate structure between adjacent channels of the plurality of horizontal channels.

In an aspect, a method for fabricating a FET structure includes providing a gate structure, disposed between a first vertical S/D structure and a second vertical S/D structure, the gate structure comprising a channel structure comprising a plurality of vertically-stacked, horizontal channels connecting the first vertical S/D structure to the second vertical S/D structure horizontally through a vertical metal gate structure that at least partially surrounds the plurality of horizontal channels; and providing a backside ILD layer disposed below the vertical metal gate structure and separated from some portions of the vertical metal gate structure by an STI layer, wherein a first thickness of the vertical metal gate structure below a bottom channel of the plurality of horizontal channels is larger than a second thickness of the vertical metal gate structure between adjacent channels of the plurality of horizontal channels.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1A is a top view of a portion of a conventional semiconductor structure of an integrated circuit (IC) device without backside power or signal routing.

FIG. 1B is a schematic diagram illustrating the circuit created by the semiconductor structure illustrated in FIG. 1A.

FIGS. 2A and 2B are top views of a portion of a semiconductor structure of an IC device, according to aspects of the disclosure.

FIGS. 2C-2E are cross-sectional views of a semiconductor structure of an IC device, according to aspects of the disclosure.

FIGS. 3A-3D are cross-sections that illustrate steps in a process for fabricating a backside contact over active gate (BSCOAG) and/or a backside gate contact (BSGC) according to aspects of the disclosure.

FIG. 4 is a flowchart of an example process associated with fabrication of a BSCOAG and/or a BSGC, according to aspects of the disclosure.

FIG. 5 illustrates a mobile device in accordance with some examples of the disclosure.

FIG. 6 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

A field effect transistor (FET) structure and method for making the same is disclosed. In some aspects, a FET structure comprises a gate structure, disposed between a first vertical source/drain (S/D) structure and a second vertical S/D structure, the gate structure comprising a channel structure comprising a plurality of vertically-stacked, horizontal channels connecting the first vertical S/D structure to the second vertical S/D structure horizontally through a vertical metal gate structure that at least partially surrounds the horizontal channels. The FET structure also includes a backside inter-layer dielectric (ILD) layer disposed below the vertical metal gate structure and separated from some portions of the vertical metal gate structure by a shallow trench isolation (STI) layer, wherein a first thickness T1 of the vertical metal gate structure below a bottom channel of the plurality of horizontal channels is larger than a second thickness T2 of the vertical metal gate structure between adjacent channels of the plurality of horizontal channels. In some aspects, the active portion of the gate structure (i.e., containing the channel structure and the vertical metal gate structure) is in direct contact with the backside ILD layer, and the non-active portion of the gate structure (i.e., not containing a channel structure and a vertical metal gate structure) is separated from the backside ILD by the STI layer. In some aspects, a backside contact structure electrically couples to the vertical metal gate structure through the backside ILD layer, the STI layer, and a high-K dielectric at the bottom of the gate structure—in which case it is referred to as a “backside gate contact” (BSGC)—or through the backside ILD layer and the high-K dielectric at the bottom of the gate structure—in which case it is referred to as a “backside gate contact over active gate” (BSCOAG). In some aspects, the BSCOAG structure is used as a gate isolation tiedown that electrically isolates a circuit from a neighboring circuit. For example, the gate of a pFET is tied to VDD and the gate of an nFET is tied to VSS, forcing both of those transistors to the OFF condition.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an integrated circuit device and a manufacturing method of making the integrated circuit device. Some aspects more specifically relate to an integrated circuit device having a back side gate contact over active gate and a back side gate contact through shallow trench isolation. These contacts are applicable to gate-all-around structures and compatible with backside power distribution networks.

Particular aspects of the subject matter described in this disclosure can be implemented to realize one or more of the following potential advantages. A backside gate contact, constructed using a unique fabrication process, allows a backside connection to a field effect transistor (FET) gate, including gate-all-around (GAA) topologies, either through a gate active area or through shallow trench isolation (STI). The former is herein referred to as a backside contact on active gate (BSCOAG) and the latter is herein referred to a backside gate contact (BSGC). These two gate contact structures provide standard cells with access to the backside for signal routing. In contrast, conventional standard cell designs have backside connections only for power routing, not for signal routing. Access to backside signal routing allows both a reduction in standard cell size and a reduction in parasitic resistance and capacitance, providing standard cell performance improvements and area reduction/cell compaction.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

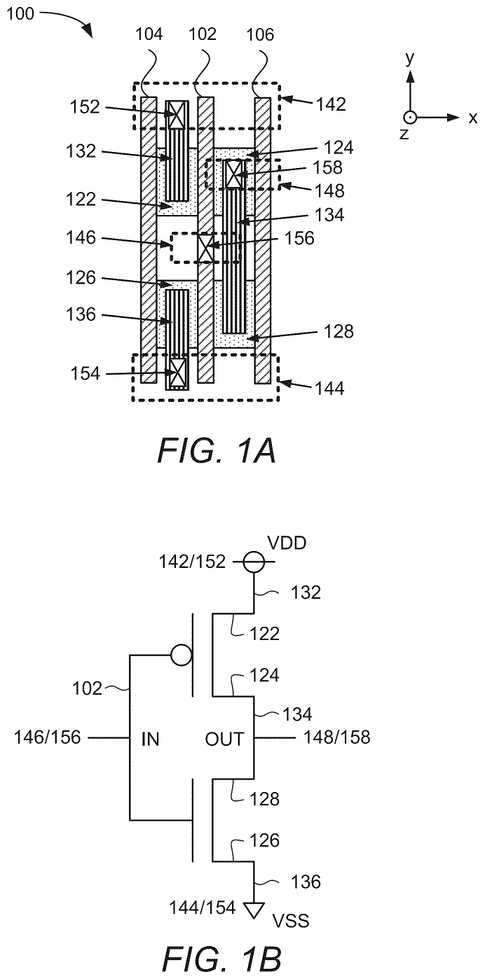

FIG. 1A is a top view of a portion of a semiconductor structure 100 of a conventional integrated circuit (IC) device without backside power or signal routing. In some aspects, FIG. 1A merely shows some elements of the semiconductor structure 100 for illustration purposes, and other elements above and/or below the elements shown in FIG. 1A may be disposed but not shown in FIG. 1A.

As shown in FIG. 1A, the semiconductor structure 100 includes gate stacks 102, 104, and 106 spaced along a first direction (e.g., the x direction) and having a length along a second direction (e.g., the y direction). The semiconductor structure 100 also includes a source/drain (S/D) structure 122 between the gate stacks 102 and 104, an S/D structure 124 between the gate stacks 102 and 106, an S/D structure 126 between the gate stacks 102 and 104, and an S/D structure 128 between the gate stacks 102 and 106. The S/D structure 122 and the S/D structure 126 are disposed apart from each other in the second direction (e.g., the y direction), and the S/D structure 124 and the S/D structure 128 are disposed apart from each other in the second direction (e.g., the y direction).

A portion of the gate stack 102 adjacent to the S/D structure 122 and the S/D structure 124 may be configured as a first gate structure, and a first channel structure may be formed through the first gate structure in the first direction. The S/D structure 122 and the S/D structure 124 may be electrically coupled to the first channel structure. Also, a portion of the gate stack 102 adjacent to the S/D structure 126 and the S/D structure 128 may be configured as a second gate structure, and a second channel structure may be formed through the second gate structure in the first direction. The S/D structure 126 and the S/D structure 128 may be electrically coupled to the second channel structure. In some aspects, the S/D structure 122 and the S/D structure 124 may have a first doping type, and the S/D structure 126 and the S/D structure 128 may have a second doping type different from the first doping type.

In some aspects, the first gate structure, the first channel structure, the S/D structure 122, and the S/D structure 124 may be configured as a first transistor of a first type; and the second gate structure, the second channel structure, the S/D structure 126, and the S/D structure 128 may be configured as a second transistor of a second type. In some aspects, the gate stacks 104 and 106 may be configured as dummy gates that are to be biased to electrically separate the S/D structures 122, 124, 126, and 128 from neighboring S/D structures (not shown).

As shown in FIG. 1A, the semiconductor structure 100 includes a contact 132 electrically coupled to the S/D structure 122, a contact 134 electrically coupled to the S/D structure 124 and the S/D structure 128, and a contact 136 electrically coupled to the S/D structure 126. The semiconductor structure 100 includes a first conductive structure 142, a second conductive structure 144, a third conductive structure 146, and a fourth conductive structure 148. The semiconductor structure 100 further includes a contact 152 electrically coupling the contact 132 to the first conductive structure 142, a contact 154 electrically coupling the contact 136 to the second conductive structure 144, a contact 156 electrically coupling the gate stack 102 to the third conductive structure 146, and a contact 158 electrically coupling the contact 134 to the fourth conductive structure 148.

FIG. 1B is a schematic diagram illustrating an exemplary circuit created by the semiconductor structure 100. In some aspects, the portion of the semiconductor structure 100 shown in FIG. 1A forms an inverter and may be used as a standard cell of an inverter for manufacturing the IC device. In some aspects, the first conductive structure 142 may be a first power line configured to carry a first power voltage (e.g., VDD), and the second conductive structure 144 may be a second power line configured to carry a second power voltage (e.g., VSS or ground). In some aspects, the third conductive structure 146 may be a signal line configured to carry a gate voltage for controlling the first gate structure of the first transistor and the second gate structure of the second transistor, e.g., the IN pin of the inverter. In some aspects, the fourth conductive structure 148 may be a signal line configured to carry a S/D voltage at the S/D structure 124 of the first transistor and the S/D structure 128 of the second transistor, e.g., the OUT pin of the inverter.

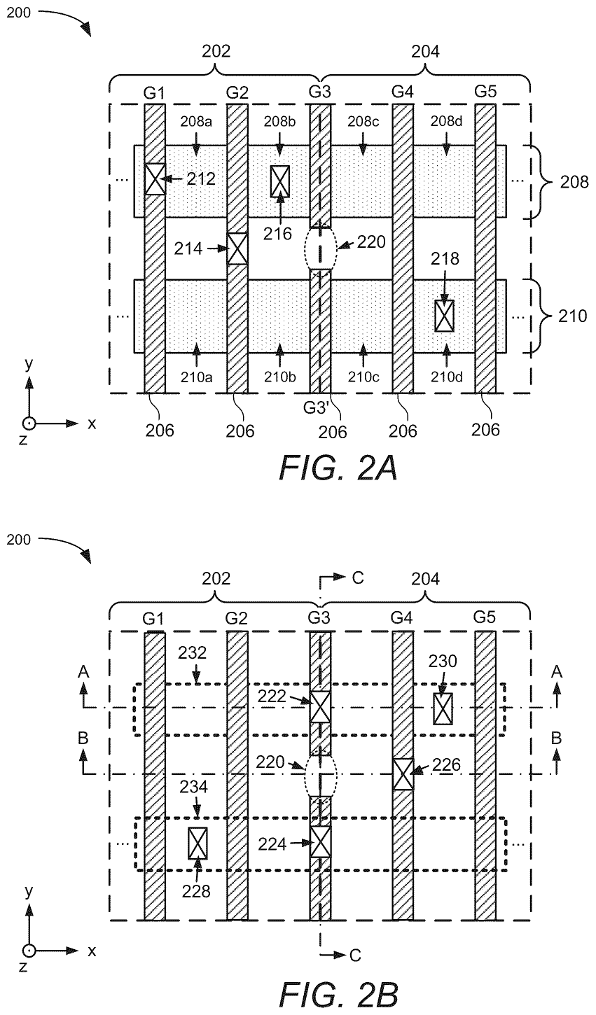

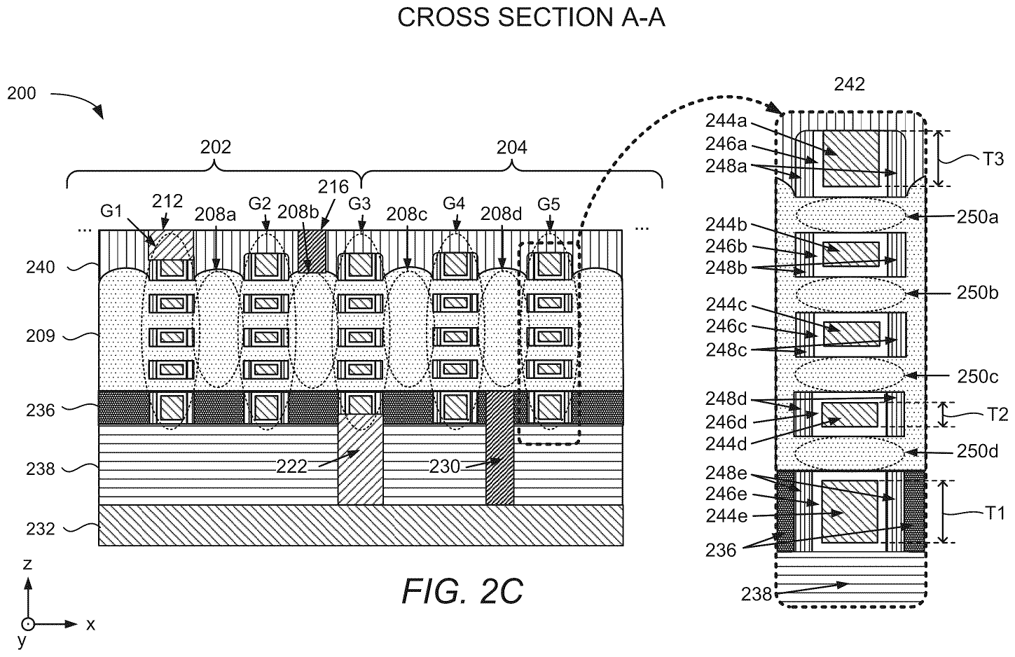

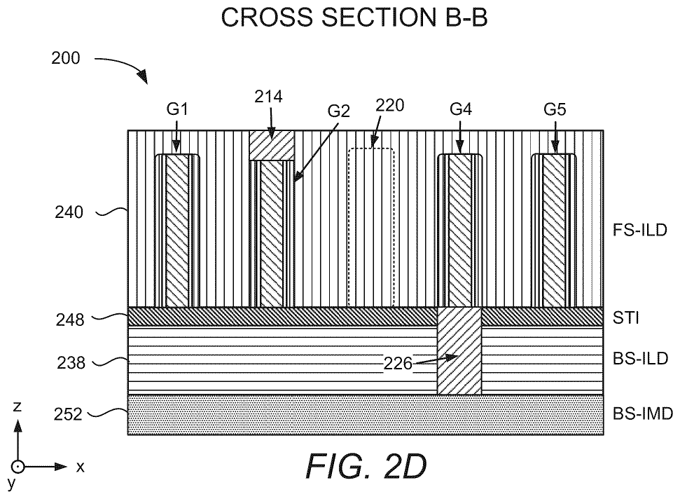

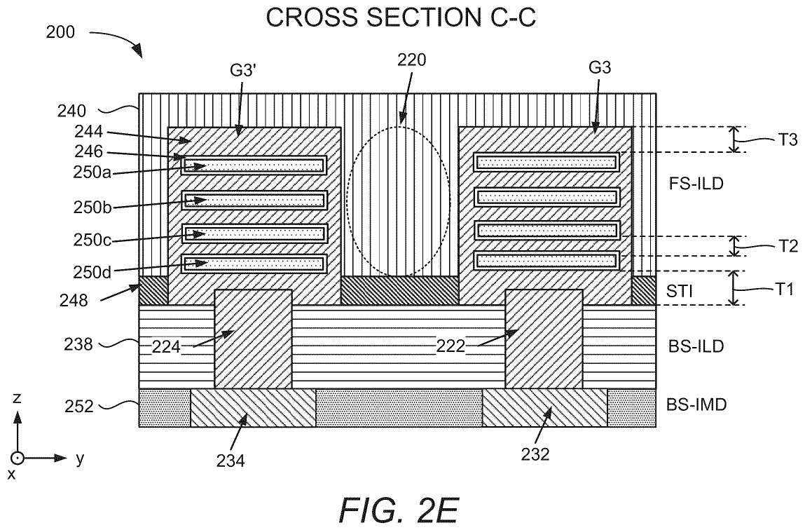

FIG. 2A and FIG. 2B are top views of a portion of a semiconductor structure 200 of an IC device, with emphasis of elements at different vertical regions thereof, according to aspects of the disclosure. In particular, the elements shown in FIG. 2A shows the elements that may be above the elements shown in FIG. 2B in a vertical direction (e.g., the z direction corresponding to a direction leaving the plane of the drawing sheet). In some aspects, FIGS. 2A and 2B merely show some elements of the semiconductor structure 200 for illustration purposes, and other elements above and/or below the elements shown in FIGS. 2A and 2B may be disposed but not shown in FIGS. 2A and 2B.

FIG. 2A and FIG. 2B show portions of two standard cells, cell 202 and cell 204, placed side by side. Each cell has multiple gate structures 206, a first set of S/D structures 208 and a second set of S/D structures 210. In some aspects, the S/D structures are epitaxial layers. For ease of description, the gate structures 206 are labeled G1, G2, G3, G4, and G5. The first set of S/D structures 208 is further divided into S/D 208a, S/D 208b, S/D 208c, and S/D 208d. The second set of S/D structures 210 is further divided into S/D 210a, S/D 210b, S/D 210c, and S/D 210d. Although five gate structures are shown, it will be appreciated that there may be a non-specific number of gate structures in a cell or a FET structure.

FIG. 2A shows the placement of a frontside gate contact 212 over an active portion of and connected to gate G1. A frontside gate contact over an active portion of a gate may be referred to herein as a “frontside contact over active gate” (FSCOAG).

FIG. 2A also shows a frontside gate contact 214 over a non-active portion of and connected to gate G2. A frontside gate contact over a non-active portion of a gate may be referred to herein as “frontside gate contact” (FSGC).

FIG. 2A also shows a frontside S/D contact 216 connected to S/D 208b. FIG. 2A also shows a frontside S/D contact 218 connected to S/D 210d. A frontside S/D contact may be referred to herein as a “frontside S/D contact” (FSDC).

In the example shown in FIG. 2A and FIG. 2B, a portion 220 of gate G3 has been removed, effectively splitting the gate into a first portion G3 over S/D structure 208 and a second portion G3′ over S/D structure 210. As will be explained in more detail below, G3 and G3′ may be tied to power supplies in order to turn the corresponding active portions of the gate off, which allows the split gate to electrically isolate cell 202 from cell 204.

It is noted that the generic term “frontside contact” (FSC) may be used to refer collectively to all of the types of frontside contacts and may be used to refer to a specific type FSCOAG, FSGC, or FSDC, depending on the context.

FIG. 2B shows the placement of a backside gate contact 222 over an active portion of and connected to G3. FIG. 2B also shows a backside gate contact 224 over an active portion of and connected to G3′. A backside gate contact over an active portion of a gate may be referred to as a “backside contact over active gate” (BSCOAG).

FIG. 2B also shows a backside gate contact 226 under a non-active portion of and connected to G4. A backside contact over a non-active portion of a gate may be referred to herein as a “backside gate contact” (BSGC).

FIG. 2B also shows a backside S/D contact 228 connected to S/D 210a. FIG. 2B also shows a backside S/D contact 230 connected to S/D 208d. Backside contacts to S/D regions may be referred to herein as a “backside S/D contact” (BSDC).

It is noted that the generic term “backside contact” (BSC) may be used to refer collectively to all of the types of backside contacts and may be used to refer to a specific type BSCOAG, BSGC, or BSDC, depending on the context. It will be understood that any of the types of backside contacts may be used for signal routing, power routing, gate isolation tiedown, other purposes, or a combination thereof.

FIG. 2B also shows a backside metal structure 232, to which the BSCOAG 222 and the BSDC 230 are connected. FIG. 2B also shows a backside metal structure 234, to which the BSCOAG 224 and the BSDC 228 are connected. The backside metal structures may be used for power supplies, for local routing, or for both. For example, in some aspects, the backside metal structure 232 carries VDD and the backside metal structure 234 carries VSS.

FIG. 2C is a cross-sectional view of the semiconductor structure 200 along cut line A-A. FIG. 2C shows the cross section of cell 202 and cell 204, showing cross sections of gates G1-G5 and the S/D structure 208.

FIG. 2C also shows an epitaxial (EPI) stop layer 236 located below the S/D structure 208 and surrounding a bottom portion of each gate stack. The EPI stop layer 236 is located in the S/D areas to block the EPI growth from the substrate, and to serve as an etch stop layer for the BSDCs (but not for the BSGCs). The EPI stop layer 236 also serves as an isolation layer between the BSCOAG and the S/D structures to prevent a short circuit between the BSCOAG and the S/D structures. Example materials used for the EPI stop layer 236 include, but are not limited to, SiON, SiCON, SiN, or a combination thereof. In some aspects, a lower surface of the EPI stop layer 236 may be at about the same level of a lower surface of the gate structures of the gate stacks.

FIG. 2C also shows a backside inter-layer dielectric (BS-ILD) layer 238 that separates the EPI stop layer 236 from the backside metal structure 232. FIG. 2C also shows a frontside inter-layer dielectric (FS-ILD) layer 240 that covers the S/D structure 208 and the gates G1-G5. FIG. 2C also shows the FSCOAG 212 connected to the top of gate G1 through the FS-ILD layer 240. FIG. 2C also shows the FSDC 216 connected to the top of S/D 208b through the FS-ILD layer 240. FIG. 2C also shows the BSCOAG 222 connected to the bottom of gate G3 through the BS-ILD layer 238. FIG. 2C also shows the BSDC 230 connected to the bottom of S/D 208d through the BS-ILD layer 238. In the example shown in FIG. 2C, the BSCOAG 222 and the BSDC 230 are connected to backside metal structure 232.

In FIG. 2C, an enlarged area 242 shows the details of a portion of a gate stack. In the example shown in FIG. 2C, each gate stack includes five gate portions, each including a respective gate electrode (e.g., gate electrodes 244a-e) and a respective gate dielectric structure (e.g., gate dielectric structures 246a-c). In this disclosure, all the gate electrodes in a gate stack may be collectively referred to as a gate electrode structure 244. In some aspects, a top gate portion of the gate stack may include gate spacers 248a on sidewalls of the gate dielectric structure 246a. In some aspects, the gate portions of the gate stack other than the top gate portion may include inner spacers (e.g., inner spacers 248b-c) on sidewalls of the respective gate dielectric structure (e.g., gate dielectric structures 246b-c). The enlarged area 242 also shows the locations of channels 250a-d, through which charge carriers travel horizontally from left to right or from right to left in the figure.

As shown in FIG. 2C, a first thickness T1 of the gate electrode below a bottom channel 250d is larger than a second thickness T2 of the gate electrode between the adjacent channels 250a-d. Thus, the inner gate electrodes 244b-d have a second thickness T2 and the bottom gate electrode 244e has a first thickness T1 that is larger than T2. The larger thickness T1 provides a good margin for the etching step that creates the backside gate contacts. In particular, the additional thickness provides a larger process margin during the etch step that provides access to the bottom gate electrode 244e by a BSCOAG 222 through the BS-ILD layer 238. In some aspects, T1 is twice as thick as T2. In some aspects, T1 is more than twice as thick as T2. In some aspects, T1 is thicker than T2 but less than twice as thick as T2. In some aspects, T1 is 1.3-2.0 times thicker than T2. In some aspects, a third thickness T3 of the gate electrode above a top channel 250a is larger than the second thickness T2. This larger thickness T3 also provides a good margin for the etching step that creates the frontside gate contacts.

In the embodiment illustrated in FIG. 2C, the gate stack is a gate-all-around (GAA) design that surrounds one or more channels, e.g., channel 250a, channel 250b, channel 250c, and so on, but the BSGCs disclosed herein are also applicable to finFETs and other FET designs. The BSCOAGs disclosed herein won't apply to finFETs since there is no gate material underneath a finFET channel to which a BSCOAG could make contact.

Thus, in the embodiment shown in FIG. 2C, the gate stacks G1-G5 comprise a gate structure, disposed between a first vertical S/D structure and a second vertical S/D structure, the gate structure comprising a channel structure comprising a plurality of vertically-stacked, horizontal channels connecting the first vertical S/D structure to the second vertical S/D structure horizontally through a vertical metal gate structure that at least partially surrounds the plurality of horizontal channels, wherein a first thickness T1 of the metal gate electrode below a bottom channel of the plurality of horizontal channels is larger than a second thickness T2 of the metal gate electrode between the adjacent channels of the plurality of horizontal channels.

FIG. 2D is a cross-sectional view of the semiconductor structure 200 along cut line B-B. FIG. 2D shows a cross section of gates G1-G5 where there are no flanking S/D structures and no channels (i.e., not over an active region) and where the gate stacks are separated by the FS-ILD 240. As shown in FIG. 2D, the gate stacks are separated from the BS-ILD layer 238 by a shallow trench isolation (STI) layer 248. As shown in FIG. 2D, a backside inter-metal dielectric (BS-IMD) layer 252 is disposed below the BS-ILD layer 238.

FIG. 2D also shows the FSGC 214 in contact with G2 through the FS-ILD layer 240. FIG. 2D also shows the BSGC 226 in contact with a portion of the bottom surface of the gate stack of gate G4 through the STI layer 248 and the BS-ILD layer 238.

FIG. 2E is a cross-sectional view of the semiconductor structure 200 along cut line C-C. FIG. 2E shows a cross section of gates G3 and G3′ as well as the portion 220 of the gate stack that was removed to create the two parts G3 and G3′. FIG. 2E also shows channels 250a-d, gate dielectric structures 246, and gate electrode structures 244. As shown in FIG. 2E, the gate stacks are separated from the BS-ILD layer 238 by STI layer 248. The BSCOAG 224 connects to the backside metal structure 234 through the BS-ILD layer 238, and the BSCOAG 222 connects to the backside metal structure 232 through the BS-ILD layer 238. The backside metal structures are isolated from each other by the BS-IMD layer 252. FIG. 2E shows an example of “gate isolation tiedown”, in which a gate is split so that one portion is over a pFET and another portion is over an nFET, and where the gate of the pFET is tied to VDD and the gate of the nFET is tied to VSS, turning them both off. For example, if gate G3 is a gate of a pFET and gate G3′ is a gate of an nFET, and if backside metal structure 232 carries VDD and backside metal structure 234 carries VSS, then gate G3 and G3′ create a gate isolation tiedown that isolates the circuitry of cell 202 from the circuitry of cell 204.

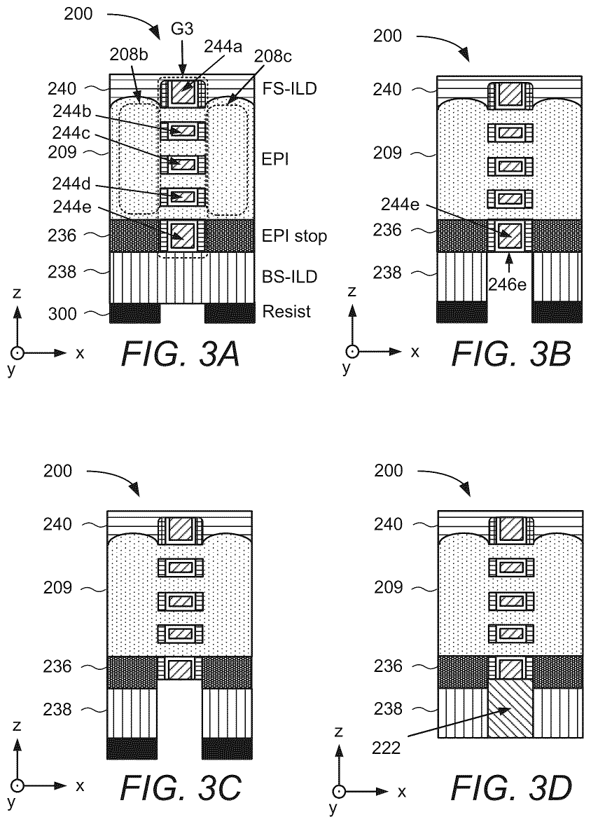

FIGS. 3A-3D are cross-sections that illustrate steps in a process for fabricating a BSCOAG according to aspects of the disclosure. As shown in FIG. 3A, the process starts with a semiconductor structure 200 comprising a gate stack, e.g., gate G3, with channels connecting a first S/D structure 208b and a second S/D structure 208c within an epitaxial layer 209, itself disposed within an FS-ILD layer 240. An EPI stop layer 236 separates the epitaxial layer 209 from a BS-ILD layer 238. In the example shown in FIGS. 3A-3D, the gate stack comprises a GAA structure, but the same principles may be applied to finFET or other structure.

FIG. 3A illustrates the result after application of a resist layer 300 and a patterning process, which may be referred to herein as a BSCOAG/BSGC lithography step.

FIG. 3B illustrates the result after a first etching process that etches through the BS-ILD layer 238 but stops at the high-K gate dielectric structure 246c.

FIG. 3C illustrates the result after a second etching process that etches through the high-K gate dielectric structure 246e but stops at the gate electrode 244c.

FIG. 3D illustrates the result after removal of the resist layer 300, metallization of a BSCOAG 222 (or a BSGC), and a planarization step such as chemical/mechanical polishing. Materials for the BSCOAGs and BSGCs may include, but are not limited to, tungsten, cobalt, molybdenum, and ruthenium.

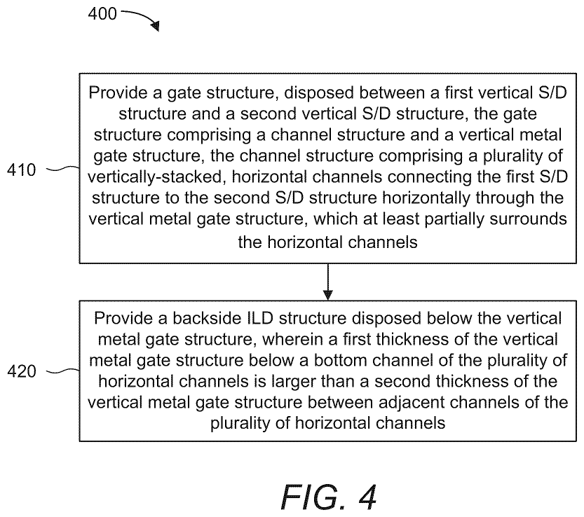

FIG. 4 is a flowchart of an example process 400 associated with fabrication of a GAA FET transistor structure, according to aspects of the disclosure.

As shown in FIG. 4, process 400 may include, at block 410, providing a gate structure, disposed between a first vertical S/D structure and a second vertical S/D structure, the gate structure comprising a channel structure and a vertical metal gate structure, the channel structure comprising a plurality of vertically-stacked, horizontal channels connecting the first vertical S/D structure to the second vertical S/D structure horizontally through the vertical metal gate structure that at least partially surrounds the plurality of horizontal channels.

In some aspects, at least one of the first vertical S/D structure and the second vertical S/D structure comprises an EPI layer.

In some aspects, the vertical metal gate structure comprises a high-K dielectric layer at least partially surrounding a work function metal layer.

In some aspects, the channel structure is contained within a first portion of the vertical metal gate structure and not within a second portion of the vertical metal gate structure.

In some aspects, the second portion of the vertical metal gate structure is separated from the backside ILD structure by the STI layer.

As further shown in FIG. 4, process 400 may include, at block 420, providing a backside ILD layer disposed below the vertical metal gate structure, wherein a first thickness T1 of the vertical metal gate structure below a bottom channel of the plurality of horizontal channels is larger than a second thickness T2 of the vertical metal gate structure between adjacent channels of the plurality of horizontal channels.

In some aspects, process 400 may further include providing a backside contact structure electrically coupled to the vertical metal gate structure through the backside ILD layer or through the backside ILD layer and the STI layer.

In some aspects, the backside contact structure is electrically coupled to a backside metallization structure disposed below the backside ILD layer.

In some aspects, the backside contact structure comprises a backside gate isolation tiedown, e.g., to tie a portion of the vertical metal gate structure to VDD or VSS.

In some aspects, process 400 may further include providing an S/D via connected to the first vertical S/D structure through the backside ILD layer.

In some aspects, process 400 may further include providing a frontside ILD layer that at least partially encloses the gate structure.

In some aspects, process 400 may further include providing an S/D via connected to the first vertical S/D structure through the frontside ILD layer.

Process 400 may include additional implementations, such as any single implementation or any combination of implementations described above and/or in connection with one or more other processes described elsewhere herein. Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

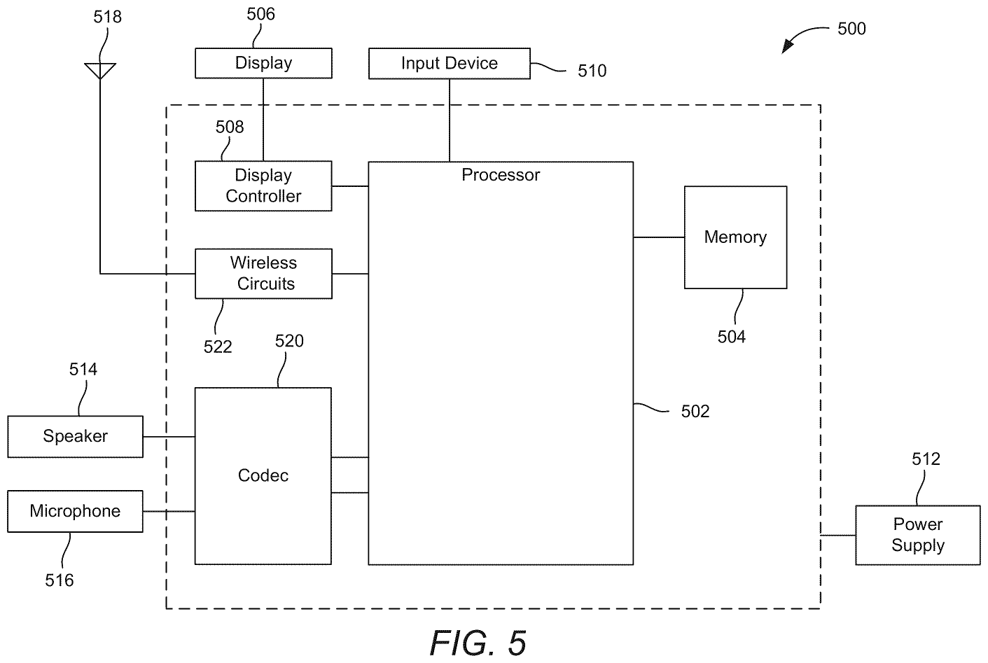

FIG. 5 illustrates a mobile device 500, according to aspects of the disclosure. In some aspects, the mobile device 500 may be implemented by including one or more IC devices manufactured based on the examples described in this disclosure.

In some aspects, mobile device 500 may be configured as a wireless communication device. As shown, mobile device 500 includes processor 502. Processor 502 may be communicatively coupled to memory 504 over a link, which may be a die-to-die or chip-to-chip link. Mobile device 500 also includes display 506 and display controller 508, with display controller 508 coupled to processor 502 and to display 506. The mobile device 500 may include input device 510 (e.g., physical, or virtual keyboard), power supply 512 (e.g., battery), speaker 514, microphone 516, and wireless antenna 518. In some aspects, the power supply 512 may directly or indirectly provide the supply voltage for operating some or all of the components of the mobile device 500.

In some aspects, FIG. 5 may include coder/decoder (CODEC) 520 (e.g., an audio and/or voice CODEC) coupled to processor 502; speaker 514 and microphone 516 coupled to CODEC 520; and wireless circuits 522 (which may include a modem, RF circuitry, filters, etc.) coupled to wireless antenna 518 and to processor 502.

In some aspects, one or more of processor 502, display controller 508, memory 504. CODEC 520, and wireless circuits 522 may include one or more IC devices including semiconductor structures manufactured according to the examples described in this disclosure.

It should be noted that although FIG. 5 depicts a mobile device 500, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

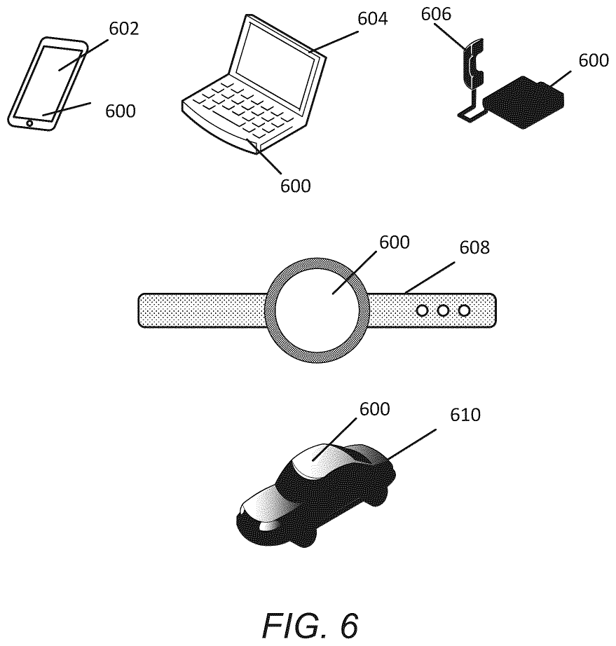

FIG. 6 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 602, a laptop computer device 604, a fixed location terminal device 606, a wearable device 608, or automotive vehicle 610 may include a semiconductor device 600 (e.g., semiconductor structure 200) as described herein. The devices 602, 604, 606 and 608 and the vehicle 610 illustrated in FIG. 6 are merely exemplary. Other apparatuses or devices may also feature the semiconductor device 600 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A field effect transistor (FET) structure, comprising: a gate structure, disposed between a first vertical source/drain (S/D) structure and a second vertical S/D structure, the gate structure comprising a channel structure and a vertical metal gate structure, the channel structure comprising a plurality of vertically-stacked, horizontal channels connecting the first vertical S/D structure to the second vertical S/D structure horizontally through the vertical metal gate structure that at least partially surrounds the plurality of horizontal channels; and a backside inter-layer dielectric (ILD) layer disposed below the vertical metal gate structure, wherein a first thickness of the vertical metal gate structure below a bottom channel of the plurality of horizontal channels is larger than a second thickness of the vertical metal gate structure between adjacent channels of the plurality of horizontal channels.

Clause 2. The FET structure of clause 1, wherein a third thickness of the vertical metal gate structure above a top channel of the plurality of horizontal channels is larger than the second thickness of the vertical metal gate structure between adjacent channels of the plurality of horizontal channels.

Clause 3. The FET structure of any of clauses 1 to 2, further comprising a backside contact structure electrically coupled to the vertical metal gate structure through the backside ILD layer or through the backside ILD layer and a shallow trench isolation (STI) layer.

Clause 4. The FET structure of clause 3, wherein the backside contact structure is electrically coupled to a backside metallization structure disposed below the backside ILD layer.

Clause 5. The FET structure of any of clauses 3 to 4, wherein the backside contact structure comprises a backside gate isolation tiedown.

Clause 6. The FET structure of any of clauses 1 to 5, further comprising a backside S/D via connected to the first vertical S/D structure through the backside ILD layer.

Clause 7. A method for fabricating a FET structure, the method comprising: providing a gate structure, disposed between a first vertical S/D structure and a second vertical S/D structure, the gate structure comprising a channel structure and a vertical metal gate structure, the channel structure comprising a plurality of vertically-stacked, horizontal channels connecting the first vertical S/D structure to the second vertical S/D structure horizontally through the vertical metal gate structure that at least partially surrounds the plurality of horizontal channels; and providing a backside ILD layer disposed below the vertical metal gate structure, wherein a first thickness of the vertical metal gate structure below a bottom channel of the plurality of horizontal channels is larger than a second thickness of the vertical metal gate structure between adjacent channels of the plurality of horizontal channels.

Clause 8. The method of clause 7, wherein a third thickness of the vertical metal gate structure above a top channel of the plurality of horizontal channels is larger than the second thickness of the vertical metal gate structure between adjacent channels of the plurality of horizontal channels.

Clause 9. The method of any of clauses 7 to 8, further comprising providing a backside contact structure electrically coupled to the vertical metal gate structure through the backside ILD layer or through the backside ILD layer and a STI layer.

Clause 10. The method of clause 9, wherein the backside contact structure is electrically coupled to a backside metallization structure disposed below the backside ILD layer.

Clause 11. The method of any of clauses 9 to 10, wherein the backside contact structure comprises a backside gate isolation tiedown.

Clause 12. The method of any of clauses 9 to 11, wherein providing the backside contact structure electrically coupled to the vertical metal gate structure through the backside ILD layer or through the backside ILD layer and the STI layer comprises: etching the backside ILD layer to expose a dielectric layer of the vertical metal gate structure below the bottom channel of the plurality of horizontal channels; etching the dielectric layer to expose a gate electrode of the vertical metal gate structure below the bottom channel of the plurality of horizontal channels; and performing a metallization process to create the backside contact structure electrically coupled to the vertical metal gate structure below the bottom channel of the plurality of horizontal channels.

Clause 13. The method of any of clauses 7 to 12, further comprising providing a backside S/D via connected to the first vertical S/D structure through the backside ILD layer.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A field effect transistor (FET) structure, comprising:
a gate structure, disposed between a first vertical source/drain (S/D) structure and a second vertical S/D structure, the gate structure comprising a channel structure and a vertical metal gate structure, the channel structure comprising a plurality of vertically-stacked, horizontal channels connecting the first vertical S/D structure to the second vertical S/D structure horizontally through the vertical metal gate structure that at least partially surrounds the plurality of horizontal channels; and
a backside inter-layer dielectric (ILD) layer disposed below the vertical metal gate structure,
wherein a first thickness of the vertical metal gate structure below a bottom channel of the plurality of horizontal channels is larger than a second thickness of the vertical metal gate structure between adjacent channels of the plurality of horizontal channels.

2. The FET structure of claim 1, wherein a third thickness of the vertical metal gate structure above a top channel of the plurality of horizontal channels is larger than the second thickness of the vertical metal gate structure between adjacent channels of the plurality of horizontal channels.

3. The FET structure of claim 1, further comprising a backside contact structure electrically coupled to the vertical metal gate structure through the backside ILD layer or through the backside ILD layer and a shallow trench isolation (STI) layer.

4. The FET structure of claim 3, wherein the backside contact structure is electrically coupled to a backside metallization structure disposed below the backside ILD layer.

5. The FET structure of claim 3, wherein the backside contact structure comprises a backside gate isolation tiedown.

6. The FET structure of claim 1, further comprising a backside S/D via connected to the first vertical S/D structure through the backside ILD layer.

7. A method for fabricating a field effect transistor (FET) structure, the method comprising:
providing a gate structure, disposed between a first vertical source/drain (S/D) structure and a second vertical S/D structure, the gate structure comprising a channel structure and a vertical metal gate structure, the channel structure comprising a plurality of vertically-stacked, horizontal channels connecting the first vertical S/D structure to the second vertical S/D structure horizontally through the vertical metal gate structure that at least partially surrounds the plurality of horizontal channels; and
providing a backside inter-layer dielectric (ILD) layer disposed below the vertical metal gate structure,
wherein a first thickness of the vertical metal gate structure below a bottom channel of the plurality of horizontal channels is larger than a second thickness of the vertical metal gate structure between adjacent channels of the plurality of horizontal channels.

8. The method of claim 7, wherein a third thickness of the vertical metal gate structure above a top channel of the plurality of horizontal channels is larger than the second thickness of the vertical metal gate structure between adjacent channels of the plurality of horizontal channels.

9. The method of claim 7, further comprising providing a backside contact structure electrically coupled to the vertical metal gate structure through the backside ILD layer or through the backside ILD layer and a shallow trench isolation (STI) layer.

10. The method of claim 9, wherein the backside contact structure is electrically coupled to a backside metallization structure disposed below the backside ILD layer.

11. The method of claim 9, wherein the backside contact structure comprises a backside gate isolation tiedown.

12. The method of claim 9, wherein providing the backside contact structure electrically coupled to the vertical metal gate structure through the backside ILD layer or through the backside ILD layer and the STI layer comprises:
etching the backside ILD layer to expose a dielectric layer of the vertical metal gate structure below the bottom channel of the plurality of horizontal channels;
etching the dielectric layer to expose a gate electrode of the vertical metal gate structure below the bottom channel of the plurality of horizontal channels; and
performing a metallization process to create the backside contact structure electrically coupled to the vertical metal gate structure below the bottom channel of the plurality of horizontal channels.

13. The method of claim 7, further comprising providing a backside S/D via connected to the first vertical S/D structure through the backside ILD layer.
